(19) United States
(12) Patent Application Publication
(10) Pub. No.: US 2021/0108338 A1
(43) Pub. Date: Apr. 15, 2021

(54) BONDED SUBSTRATE, SURFACE ACOUSTIC WAVE ELEMENT, SURFACE ACOUSTIC WAVE ELEMENT DEVICE, AND METHOD FOR MANUFACTURING BONDED SUBSTRATE

(71) Applicant: THE JAPAN STEEL WORKS, LTD., Shinagawa-ku, Tokyo (JP)

(72) Inventors: Kouhei KURIMOTO, Muroran-shi, Hokkaido (JP); Kazuhito KISHIDA, Shinagawa-ku, Tokyo (JP); Rinzo KAYANO, Muroran-shi, Hokkaido (JP); Jun MIZUNO, Shinjuku-ku, Tokyo (JP); Shoji KAKIO, Kofu-shi, Yamanashi (JP)

(73) Assignee: THE JAPAN STEEL WORKS, LTD., Shinagawa-ku, Tokyo (JP)

(21) Appl. No.: 16/969,912

(22) PCT Filed: Feb. 4, 2019
(86) PCT No.: PCT/JP2019/003861

§ 371 Date: Aug. 13, 2020

(30) Foreign Application Priority Data
Feb. 16, 2018 (JP) 2018-026361

(51) Int. Cl. C30B 33/06; C30B 33/02; C30B 29/30; H03H 3/08; H03H 9/25

(52) U.S. Cl. CPC C30B 33/06; C30B 33/02; H03H 9/25; H03H 3/08; C30B 29/30

(57) ABSTRACT

A bonded substrate includes: a quartz substrate cut at an intersection angle with a crystal X-axis; and a piezoelectric substrate laminated on the quartz substrate. Preferably, a cut angle of the quartz substrate has an angle in the range of 85 to 95 degrees with respect to the crystal X-axis. Preferably, the surface acoustic wave propagation direction of the quartz substrate has an angle of 15 to 50 degrees with respect to a crystal Y-axis. Preferably, as a piezoelectric substrate, lithium niobate or lithium tantalate is used. Preferably, the piezoelectric substrate has a thickness h having a relationship of 0.02 to 0.11λ with respect to a wavelength λ of a surface acoustic wave.

### TECHNICAL FIELD

The present invention relates to a bonded substrate utilizing a surface acoustic wave, a surface acoustic wave element, a surface acoustic wave element device, and a method for manufacturing the bonded substrate.

### BACKGROUND ART

With progress of mobile communication devices such as a mobile phone, high-performance surface acoustic wave (SAW) devices are also requested. In particular, for high-frequency and broad band trends, SAW substrates are requested to have a high-speed and high-coupling SAW mode, and excellent temperature characteristics for preventing a passband from moving due to temperature change.

Furthermore, a leaky surface acoustic wave (Leaky SAW: also called LSAW and the like) and a longitudinal-type leaky surface acoustic wave (Longitudinal-type Leaky SAW: also called LLSAW and the like) have an excellent phase velocity, and is one of propagation modes advantageous to high-frequency trend of SAW devices. However, it disadvantageously has large propagation attenuation.

For example, Patent Literature 1 proposes a technique in which a proton exchange layer is formed in the vicinity of the surface of a lithium niobate substrate, and a reverse proton exchange layer is then formed only at the surface layer, whereby losses caused by bulk wave radiation of an LLSAW are reduced.

Also in Non-Patent Literature 1 and Non-Patent Literature 2, optimizations of a substrate orientation and an electrode film thickness are attempted as techniques for low loss trend of LLSAWs.

Patent Literature 2 discloses a device obtained by bonding a SAW propagating substrate and a supporting substrate with an organic thin film layer. The propagating substrate is a lithium tantalate substrate, for example, having a thickness of 30 μm, which is pasted on a glass substrate having a thickness of 300 μm by an organic adhesive agent having a thickness of 15 μm.

Patent Literature 3 also discloses a SAW device obtained by pasting a lithium tantalate substrate (thickness: 125 μm) on a quartz glass substrate (thickness: 125 μm) by an adhesive agent.

Patent Literature 4 reports that temperature characteristics are improved by using a thinner organic adhesive layer in bonding between a lithium tantalate substrate and a supporting substrate.

However, the materials shown in Patent Literatures 1 to 4 do not sufficiently solve a problem of large propagation attenuation.

The present inventors reveal that propagation attenuation is reduced in bonding a quartz substrate and a piezoelectric substrate to each other in Non-Patent Literatures 3 to 5.

For example, in Non-Patent Literature 3, in order for a surface acoustic wave (SAW) device, an amorphous SiO₂ (α-SiO₂) intermediate layer is used during directly bond ST-cut quartz and LiTaO₃ (LT) to each other.

Non-Patent Literature 4 proposes an LLSAW obtained by bonding lithium tantalate X-cut at 31° and Y propagating and lithium niobate X-cut at 36° and Y propagating to AT-cut quartz, to provide an increased electromechanical coupling factor.

In Non-Patent Literature 5, a high coupling of longitudinal-type leaky surface acoustic wave is achieved by bonding a LiTaO₃ or LiNbO₃ thin plate and a quartz substrate to each other.

### CITATION LIST

### Patent Literature

[Patent Literature 1] Japanese Patent Laid-Open No. 2013-30829
[Patent Literature 2] Japanese Patent Laid-Open No. 2001-53579
[Patent Literature 3] Japanese Patent Laid-Open No. 2006-42008
[Patent Literature 4] Japanese Patent Laid-Open No. 2011-87079

### Non-Patent Literature

[Non-Patent Literature 1] “GHz-band surface acoustic wave devices using the second leaky mode”, Appl. Phis., vol. 36, no 9B, pp. 6083-6087, 1997
[Non-Patent Literature 2] “Characteristics of Longitudinal Leaky Surface Acoustic Wave Resonator in LiNbO₃: Analysis based on Finite Element Analytical Combined Method”, Conference of Engineering Sciences Society in the Institute of Electronics, Information and Communication Engineers, A-195, p. 196, 1996
[Non-Patent Literature 3] “2016 International Conference on Electronics Packaging (ICEP)”, Publishing by The Japan Institute of Electronics Packaging, Date of Issue: Apr. 20, 2016
[Non-Patent Literature 4] “Preprint of Graduation Thesis Event of Department of Electrical and Electronic Engineering, Technology Faculty, Yamanashi University in 2015”, Publishing by Department of Electrical and Electronic Engineering, Technology Faculty, Yamanashi University, Date of Issue: Feb. 16, 2016
[Non-Patent Literature 5] “Graduation Thesis Event of Department of Electrical and Electronic Engineering, Technology Faculty, Yamanashi University in 2015”, Event Date: Feb. 16, 2016

### SUMMARY OF INVENTION

### Technical Problem

Conventionally, a leaky surface acoustic wave (LSAW) and a longitudinal-type leaky surface acoustic wave (referred to also as LLSAW) have been proposed as a SAW. However, the use of a Longitudinal-type Leaky SAW (LLSAW) having a high-speed phase velocity attracts attention as a more excellent method for achieving high-frequency trend.

Conventionally, in the LLSAW, it has been revealed that a coupling factor is increased by two or three times with respect to a simplex substrate by bonding a LiNbO₃ (LN) thin plate or a LiTaO₃ (LT) thin plate to AT-cut 45° X-propagation quartz. It has been reported that temperature characteristics are also improved compared with the simplex substrate. However, there are problems that propagation attenuation after bonding is large and a Q value is small. The conventionally proposed technique provides an insufficient improvement in a propagation velocity.

The present invention is devised in view of the aforementioned circumstances, and an object thereof is to provide a bonded substrate, a surface acoustic wave element, and a surface acoustic wave element device which have small propagation attenuation.

### Solution to Problem

A bonded substrate according to a first aspect of the present invention includes: a quartz substrate cut at an intersection angle with a crystal X-axis; and a piezoelectric substrate laminated on the quartz substrate.

A bonded substrate according to another aspect of the present invention is the bonded substrate according to the preceding aspect, wherein a cut angle of the quartz substrate has an angle in the range of 85 to 95 degrees with respect to the crystal X-axis.

A bonded substrate according to another aspect of the present invention is the invention according to the preceding aspect, wherein: the quartz substrate has a surface acoustic wave propagation direction set on a crystal Y direction side; and the piezoelectric substrate has a surface acoustic wave propagation direction set in the propagation direction.

A bonded substrate according to another aspect of the present invention is the invention according to the preceding aspect, wherein the surface acoustic wave propagation direction of the quartz substrate has an angle of 15 to 50 degrees with respect to a crystal Y-axis.

A bonded substrate according to another aspect of the present invention is the invention according to the preceding aspect, wherein the piezoelectric substrate is lithium niobate or lithium tantalate.

A bonded substrate according to another aspect of the present invention is the invention according to the preceding aspect, wherein the piezoelectric substrate is lithium tantalate X-cut at 31° and Y propagating or lithium niobate X-cut at 36° and Y propagating.

A bonded substrate according to another aspect of the present invention is the invention according to the preceding aspect, wherein the piezoelectric substrate has a thickness h having a relationship of 0.02 to 0.11λ with respect to a wavelength λ of a surface acoustic wave.

A bonded substrate according to another aspect of the present invention is the invention according to the preceding aspect, wherein the piezoelectric substrate is for exciting a longitudinal-type leaky surface acoustic wave.

A bonded substrate according to another aspect of the present invention is the invention according to the preceding aspect, wherein an amount of surface acoustic wave propagation attenuation is 0.1 dB/λ or less with respect to a wavelength λ of a surface acoustic wave.

A surface acoustic wave element according to a first aspect of the present invention includes at least one interdigital electrode on a principal surface of the piezoelectric substrate in the bonded substrate according to any one of the aspects of the inventions of the bonded substrates.

A surface acoustic wave element device according to another aspect of the present invention, wherein the surface acoustic wave element according to the aspect is sealed in a package.

A method for manufacturing a bonded substrate according to a first aspect of the present invention, the bonded substrate including a quartz substrate and a piezoelectric substrate bonded to each other,

the method including:

cutting quartz at an intersection angle with a crystal X-axis of the quartz to provide a quartz substrate;

setting a surface acoustic wave propagation direction on a Y-axis direction side in the quartz substrate;

providing a piezoelectric substrate having a surface acoustic wave propagation direction set according to the propagation direction;

laminating the piezoelectric substrate on the quartz substrate; and

bonding the quartz substrate and the piezoelectric substrate to each other directly or with an intermediate layer interposed therebetween.

The method for manufacturing a bonded substrate according to another aspect of the present invention is the invention according to the preceding aspect including:

irradiating a bonding surface of the quartz substrate and a bonding surface of the piezoelectric substrate with ultraviolet light under a reduced pressure;

contacting the bonding surface of the quartz substrate and the bonding surface of the piezoelectric substrate with each other after the irradiation; and

pressurizing the quartz substrate and the piezoelectric substrate in a thickness direction to bond the bonding surfaces with each other.

The method for manufacturing a bonded substrate according to another aspect of the present invention is the invention according to the preceding aspect, wherein the quartz substrate and the piezoelectric substrate are heated to a predetermined temperature during the pressurization.

The method for manufacturing a bonded substrate according to another aspect of the present invention is the invention according to the preceding aspect, wherein the intermediate layer is an amorphous layer.

Hereinafter, conditions and the like which are specified in the present invention will be described.

Cut angle of quartz substrate: angle of 85 to 95 degrees with respect to crystal X-axis

The cut angle of the quartz substrate is set in order to reduce a propagation attenuation ratio in propagation of a surface acoustic wave. If the cut angle is out of the aforementioned range, the propagation attenuation ratio increases, so that the aforementioned angle range is desirable.

Surface acoustic wave propagation direction of quartz substrate: angle of 15 to 50 degrees with respect to crystal Y-axis

The propagation attenuation of the surface acoustic wave can be reduced by appropriately setting the propagation direction of the quartz substrate, and the propagation direction of the quartz substrate is desirably within an angle of 15 to 50 degrees with respect to the crystal Y-axis. If the propagation direction of the quartz substrate is out of the aforementioned range, the propagation attenuation ratio increases.

Thickness of piezoelectric substrate: thickness h of 0.02 to 0.11λ with respect to wavelength λ of surface acoustic wave

By properly setting the thickness of the piezoelectric substrate, the propagation attenuation can be reduced. Since the propagation attenuation increases if the thickness is out of the aforementioned specified range, the aforementioned thickness range is desirable.

Amount of surface acoustic wave propagation attenuation: 0.1 dB/λ or less with respect to wavelength λ of surface acoustic wave.

The propagation attenuation satisfies the aforementioned specified range, whereby useful use in a practical region can be provided.

### Advantageous Effects of Invention

The present invention can reduce the propagation attenuation of a surface acoustic wave to cause the surface acoustic wave to propagate.

### BRIEF DESCRIPTION OF DRAWINGS

FIG. 1 is a schematic diagram illustrating a bonded state of a bonded substrate of an embodiment of present invention.

FIG. 2 is a schematic diagram illustrating the bonded substrate and a surface acoustic wave element in the same embodiment.

FIG. 3 is a schematic diagram illustrating a bonded substrate and a surface acoustic wave element in another embodiment.

FIG. 4 is a schematic diagram illustrating a bonding processing apparatus used for manufacturing a bonded substrate in an embodiment of the present invention.

FIG. 5 is a diagram for explaining a bonding mode of the quartz substrate and the piezoelectric substrate in the same embodiment.

FIG. 6 is a schematic diagram illustrating a surface acoustic wave element device in the same embodiment.

FIG. 7 is a graph illustrating the comparison results of phase velocities of a related technique which is Comparative Example of Examples and Invention Example,

FIG. 8 is a graph illustrating the relationship between the thickness of LT as a piezoelectric substrate and each of an amount of propagation attenuation and a coupling factor in a related technique which is Comparative Example of Examples.

FIG. 9 is a graph illustrating the relationship between the thickness of LT as a piezoelectric substrate and each of an amount of propagation attenuation and a coupling factor in Invention Example of Examples.

FIG. 10 is a graph illustrating the relationship between the thickness of LN which is a piezoelectric substrate and each of an amount of propagation attenuation and a coupling factor in a related technique which is Comparative Example of Examples.

FIG. 11 is a graph illustrating the relationship between the thickness of LN which is a piezoelectric substrate and each of an amount of propagation attenuation and a coupling factor in Invention Example of Examples.

FIG. 12 is a graph illustrating the relationship of an amount of propagation attenuation when the cut angle of a quartz substrate is changed and LT is used as a piezoelectric substrate in Examples.

FIG. 13 is a graph illustrating the relationship of an amount of propagation attenuation when the cut angle of a quartz substrate is changed and LN is used as a piezoelectric substrate in Examples.

FIG. 14 is a graph illustrating the relationship of an amount of propagation attenuation when a propagation direction in a quartz substrate is changed and LT is used as a piezoelectric substrate in Examples.

FIG. 15 is a graph illustrating the relationship of an amount of propagation attenuation when a propagation direction in a quartz substrate is changed and LN is used as a piezoelectric substrate in Examples.

FIG. 16 is a graph illustrating the relationship between the thickness of a piezoelectric substrate and TCF in a related technique and Invention Example in which LT is used as a piezoelectric substrate in Examples.

FIG. 17 is a graph illustrating the relationship between the thickness of a piezoelectric substrate and TCF in a related technique and Invention Example in which LN is used as a piezoelectric substrate in Examples.

FIG. 18 is a diagram illustrating the analysis results of the admittance characteristics of FEM in Invention Example of Examples.

FIG. 19 is a diagram illustrating the relationship between a propagation direction and a power flow angle in Invention Example of Examples.

### DESCRIPTION OF EMBODIMENTS

Hereinafter, a bonded substrate and a surface acoustic wave element according to an embodiment of the present invention will be described with reference to the accompanying drawings.

A bonded substrate 5 includes a quartz substrate 2 and a piezoelectric substrate 3 covalently bonded via a bonding interface 4. It is desirable that the bonding interface 4 is covalently bonded.

The quartz substrate 2 preferably has a thickness of 150 to 500 μm. The piezoelectric substrate 3 preferably has a thickness corresponding to 0.02 to 1.1 wavelengths with respect to the wavelengths of a surface acoustic wave. As the present invention, the thickness of the piezoelectric substrate more desirably corresponds to 0.05 to 0.1 wavelengths with respect to the wavelengths of the surface acoustic wave, and still more desirably 0.07 to 0.08 wavelengths with respect to the wavelengths of the surface acoustic wave.

The quartz substrate 2 is used, for example, which is obtained by cutting out quartz which is obtained by growing a crystal by a hydrothermal synthesis method at an intersection angle with a crystal X-axis. The angle is preferably 85 to 95° with respect to the crystal X-axis. More preferably, it is more desirable that the lower limit of the cut angle is 88 degrees and the upper limit of the cut angle is 92 degrees. The optimal value of the cut angle is 90° with respect to the crystal X-axis.

The quartz substrate 2 is provided, in which a surface acoustic wave propagation direction is set to a crystal Y-axis direction side. In this embodiment, a surface acoustic wave propagation direction 2D is preferably set to an angle of 15 to 50 degrees with respect to a crystal Y-axis. The optimal value of the angle is a 35° in a Y direction.

The piezoelectric substrate 3 can use a proper material, and be preferably composed of lithium tantalate or lithium niobate. Preferably, an X-cut piezoelectric substrate can be used. However, in the present invention, the cut angle of the piezoelectric substrate 3 is not limited to a specific angle.

In the piezoelectric substrate 3, a surface acoustic wave propagation direction 3D is set according to a propagation direction in the quartz substrate 2.

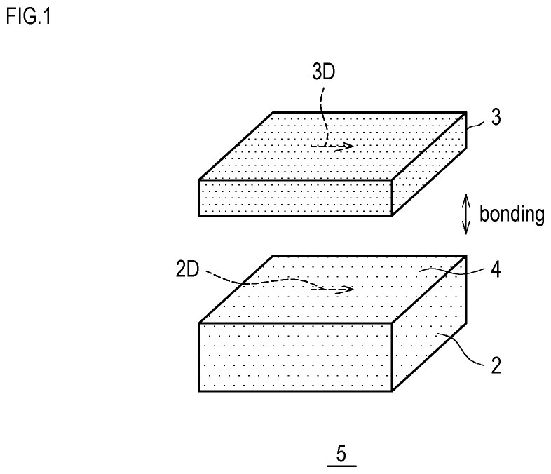

As shown in FIG. 1, the quartz substrate 2 and the piezoelectric substrate 3 are bonded to each other in a state where the propagation direction 2D of the quartz substrate 2 and the propagation direction 3D of the piezoelectric substrate 3 are set in the same direction.

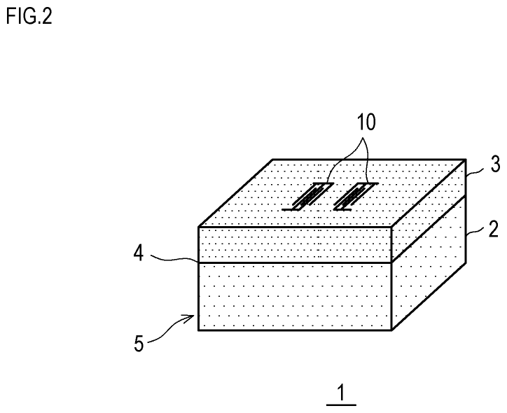

As shown in FIG. 2, a surface acoustic wave element 1 is obtained by providing an interdigital electrode 10 on the bonded substrate 5.

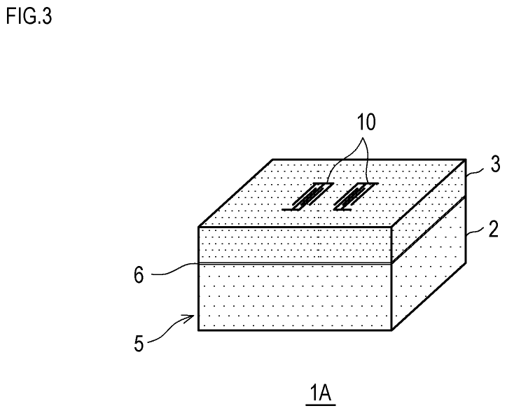

As shown in FIG. 3, a surface acoustic wave element 1A in which an amorphous layer 6 interposed between the quartz substrate and the piezoelectric substrate 3 can be provided. The same configurations as those in the aforementioned embodiment are given the same reference signs, and their description is omitted. Also in this embodiment, the quartz substrate 2 and the piezoelectric substrate 3 are bonded to each other in a state where the surface acoustic wave propagation direction of the quartz substrate 2 and the surface acoustic wave propagation direction of the piezoelectric substrate 3 are set in the same direction.

In this embodiment, when the amorphous layer 6 is interposed, a bonding interface exists between the amorphous layer 6 and the quartz substrate 2, and on the other side of the amorphous layer 6, a bonding interface exists between the amorphous layer 6 and the piezoelectric substrate 3. The material of the amorphous layer 6 is not particularly limited in the present invention, but SiO₂ and Al₂O₃ and the like can be used. The thickness of the amorphous layer is desirably 100 nm or less.

In forming the amorphous layer 6, the amorphous layer 6 can be formed by forming a thin film on the surface of the quartz substrate 2 or the piezoelectric substrate 3. Amorphous layers can be formed and bonded on both the surface of the quartz substrate 2 and the surface of the piezoelectric substrate 3.

The amorphous layer can be formed by a known method, and chemical vapor deposition or physical vapor deposition such as sputtering can be utilized.

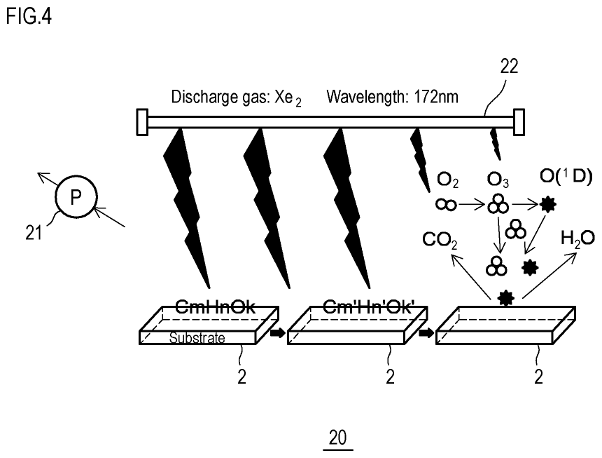

Next, manufacturing of the bonded substrate and the surface acoustic wave element will be described with reference to FIG. 4.

A quartz substrate and a piezoelectric element of predetermined materials are provided. The quartz substrate is provided by cutting quartz at an intersection angle with the crystal X-axis of the quartz. The angle of 85 to 95° with respect to the crystal X-axis is selected.

When an amorphous layer is formed on a bonding surface, with respect to one or both of the quartz substrate and the piezoelectric element targeted for the formation, deposition processing is performed on the bonding surface side. A method for the deposition processing is not particularly limited, but a thin film forming technique such as a vacuum vapor deposition method or a sputtering method can be used. For example, an amorphous layer which has a thickness of 100 nm or less can be formed on the bonding surface by Electron Cyclotron Resonance plasma deposition. This amorphous film can be formed to have a very high film density, and hence, the degree of activation of the bonding surface is high, which results in generation of more OH groups.

The quartz substrate and the piezoelectric substrate are set in a processing apparatus 20 having a tightly-sealed structure in a state where the surface acoustic wave propagation direction of the quartz substrate is preferably set to have an angle of 15 to 50 degrees with respect to a crystal Y direction and the surface acoustic wave propagation direction of the piezoelectric substrate is set to coincide with the propagation direction of the quartz substrate. In the drawing, only the quartz substrate 2 is described for simplification.

A vacuum pump 21 is connected to the processing apparatus 20, and the processing apparatus 20 is evacuated, for example, to a pressure of 10 Pa or less. Discharge gas is introduced into the processing apparatus 20, and discharge is performed by a discharge apparatus 22 in the processing apparatus 20 to generate ultraviolet light. The discharge can be performed by using a method of applying a high frequency voltage or the similar method.

The quartz substrate 2 and the piezoelectric substrate 3 are set in a state where they can be irradiated with ultraviolet light, and the bonding surfaces of the quartz substrate 2 and the piezoelectric substrate 3 are irradiated with ultraviolet light to be activated. When an amorphous layer is formed on one or both of the quartz substrate 2 and the piezoelectric substrate 3, the irradiation with ultraviolet light is performed with the surface of the amorphous layer being as the bonding surface.

On the quartz substrate 2 and the piezoelectric substrate 3 which have undergone the irradiation with ultraviolet light, in a state where the surface acoustic wave propagation direction of the quartz substrate 2 and the surface acoustic wave propagation direction of the piezoelectric substrate 3 coincide with each other, the bonding surfaces of the quartz substrate 2 and the piezoelectric substrate 3 are contacted with each other and heated at ambient temperature or a temperature of 200° C. or less, and a pressure is applied across both of them to perform bonding. The applied pressure can be set at 10 Pa and the processing time can be set to be approximately from 5 minutes to 4 hours. However, the pressure and the processing time are not particularly limited in the present invention.

By the aforementioned processing, the quartz substrate 2 and the piezoelectric substrate 3 are securely covalently bonded at the bonding interface.

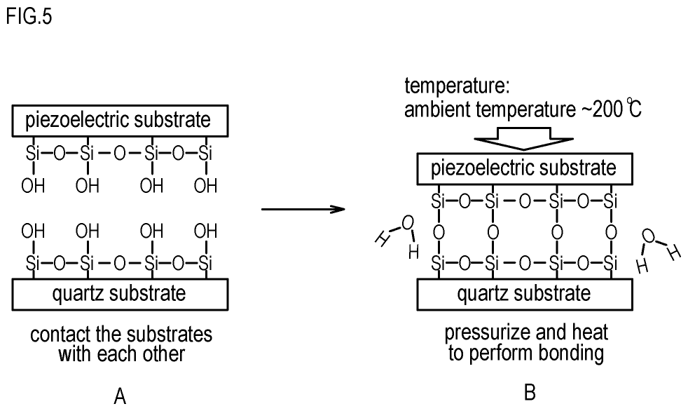

FIG. 5 shows states of the bonding surfaces of the quartz substrate 2 and the piezoelectric substrate 3.

Portion A of the figure shows a state where the bonding surfaces are activated by irradiation with ultraviolet light and OH groups are formed on the surfaces. Portion B of the figure shows a state where the substrates are contacted with each other, and pressurized and heated to perform bonding. In the bonding, the OH groups react to make the substrates to be covalently bonded with each other. Extra H₂O is removed outside during heating.

The aforementioned steps provide the bonded substrate. With respect to the bonded substrate, as shown in FIG. 3, patterns of interdigital electrodes 10 are formed on the principal surface of the piezoelectric substrate 3. A method for forming the interdigital electrodes 10 is not particularly limited, but a proper method can be used. For the shape of the interdigital electrode 10, a proper shape can be employed. The aforementioned steps provide the surface acoustic wave element 1. A surface acoustic wave is along the propagation direction set in the piezoelectric substrate 3.

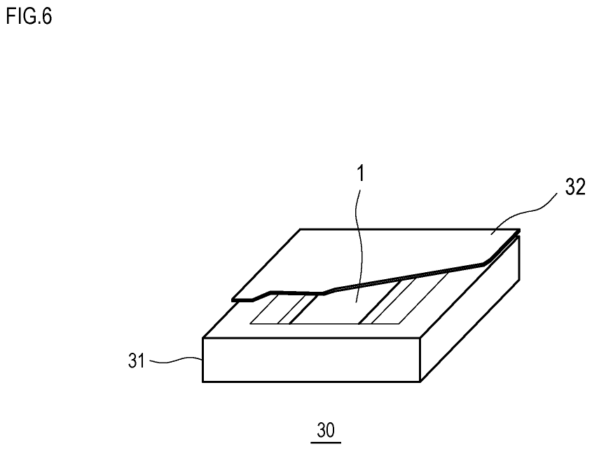

As shown in FIG. 6, the surface acoustic wave element 1 can be set in a packaging 31, connected to not-shown electrodes, and sealed with a lid 32 to be provided as a surface acoustic wave element device 30.

### Example 1

Hereinafter, Example of the present invention will be described.

A bonded substrate was obtained based on the aforementioned embodiment. A SAW resonator of an LLSAW was provided on the principal surface of a piezoelectric substrate.

In this example, as the piezoelectric substrate, lithium tantalate (LT) which was X-cut at 31° in a plane orientation and Y-propagating, and lithium niobate (LN) which was X-cut at 36° in a plane orientation and Y-propagating were used. As a quartz substrate, a substrate which was crystal-grown by a hydrothermal synthesis method and X-cut at 32° and Y-propagating or X-cut at 35° and Y-propagating to have a thickness of 250 μm was used. In Comparative Example, a quartz substrate which was AT-cut at 45° and X-propagating was used.

The bonded sample was polished on the piezoelectric substrate side to be thin. For the sample material obtained by making the piezoelectric substrate thin after bonding the quartz substrate and the piezoelectric substrate to each other, a phase velocity, an electromechanical coupling factor, and a temperature characteristic of frequency of the LLSAW were calculated according to theoretical analysis. Quartz constant of Kushibiki et al. (p. 83), lithium niobate (hereinafter, referred to as LN) constant of Kushibiki et al., and lithium tantalate (hereinafter, referred to as LT) constant (p. 377) described in “Acoustic Wave Device Technique” edited by the Japan Society for the Promotion of Science, the 150th committee of acoustic wave element technique were used for calculating.

The LLSAW having propagation attenuation was analyzed based on the method of Yamanouchi et al., and a layer structure was analyzed by using the methods of Farnell and Adler. In these analyses, the phase velocity and the propagation attenuation of the LLSAW which propagates on the layer structure are analyzed by numerically solving the acoustic wave motion equation and the charge conservation equation under a boundary condition.

A phase velocity vf of the free surface (Free) and a phase velocity vₘ when the surface of the thin plate was electrically shorted (Metallized) were obtained, and K² was obtained from K²=2×(v_{f}−vₙ)/v_{f}. A quartz supporting substrate was assumed to have a linear expansion coefficient in a propagation direction, and a temperature coefficient of frequency (TCF) of the shorted surface was calculated.

LT which was X-cut at 31° and Y-propagating was assumed as the piezoelectric substrate; in Invention Example, a quartz substrate which was X-cut at 32° and Y-propagating was assumed as the quartz substrate; and in Comparative Example, a quartz substrate which was AT-cut at 45° and X-propagating was assumed as the quartz substrate.

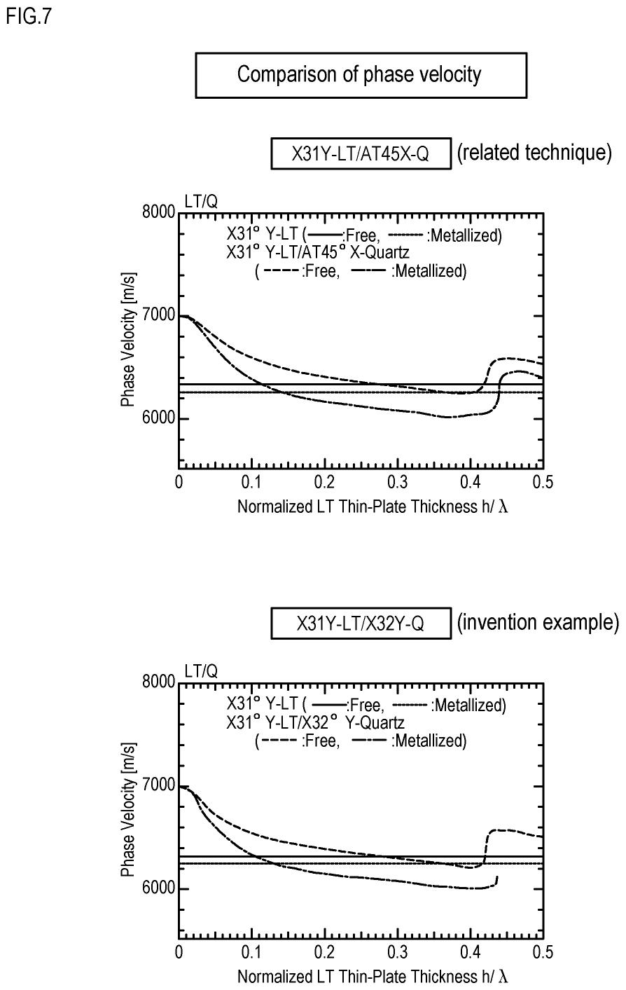

The relationship between a thickness h/λ of a piezoelectric substrate normalized by a surface acoustic wave λ and a phase velocity was obtained according to theoretical analysis, and the results were shown in FIG. 7. The phase velocity of Invention Example was equivalent to that of Comparative Example, and the characteristics of the phase velocity of 6000 m/sec or more were satisfied.

Next, according to theoretical analysis, the piezoelectric substrate of LT which was X-cut at 31° and Y-propagating and the piezoelectric substrate of LN which was X-cut at 36° and Y-propagating were assumed; in Invention Example, a quartz substrate which was X-cut at 32° and Y-propagating was assumed as the quartz substrate; in Comparative Example, a quartz substrate which was AT-cut at 45° and X-propagating was assumed, and a propagation velocity and a coupling factor K² with respect to h/λ of the piezoelectric substrate normalized by the wavelength λ of the surface acoustic wave were obtained.

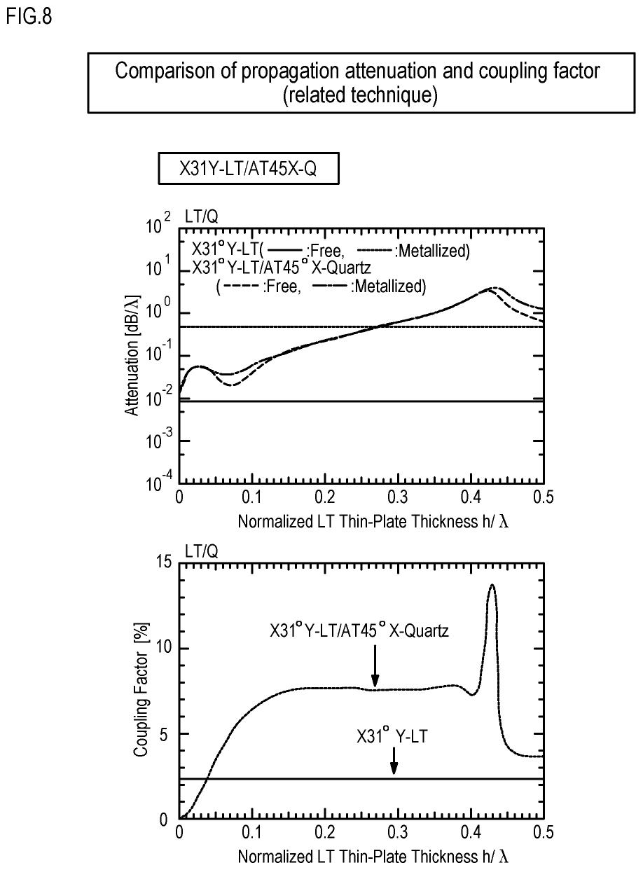

The analysis results were shown in FIG. 8 for a related technique as Comparative Example assuming the piezoelectric substrate of LT which was X-cut at 31° and Y-propagating and the quartz substrate which was AT-cut at 45° and X-propagating (hereinafter, merely referred to as related technique). Propagation attenuation is shown to be large regardless of the thickness of the piezoelectric substrate.

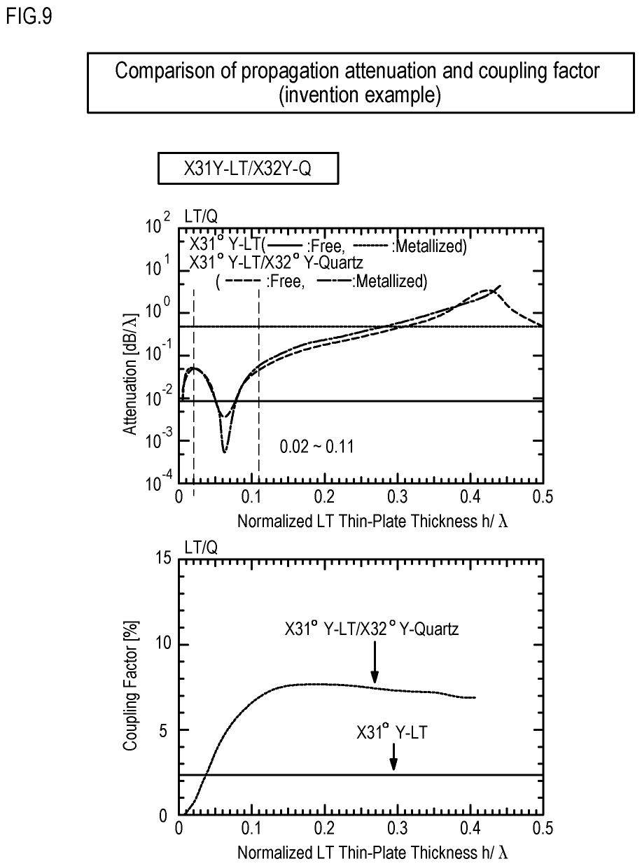

Invention Example assuming the piezoelectric substrate of LT which was X-cut at 31° and Y-propagating and the quartz substrate which was X-cut at 32° and Y-propagating was shown in FIG. 9.

In the present Invention Example, at h/λ of about 0.06, the minimum of the propagation attenuation was 0.0005 dB/λ, so that the result of highly suppressed propagation attenuation was obtained. At h/λ of 0.02 to 0.11, the propagation attenuation is satisfactorily suppressed. By respectively setting the lower and upper limits of the thickness of the piezoelectric substrate to 0.04 and 0.08, the amount of the propagation attenuation can be set to 0.01 or less. Similarly, by respectively setting the lower and upper limits to 0.05 and 0.07, the amount of the propagation attenuation can be set to 0.005 or less, which is more desirable.

The coupling factor of the present invention was 5%, which was equivalent to that of the related technique.

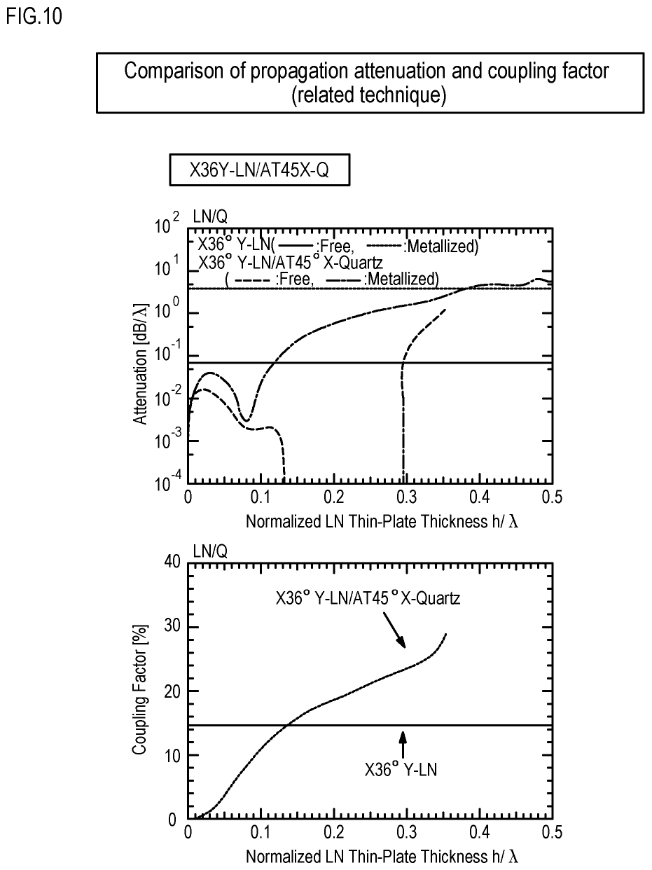

Next, the analysis results were shown in FIG. 10 for the related technique assuming the piezoelectric substrate of LN which was X-cut at 36° and Y-propagating and the quartz substrate which was AT-cut at 45° and X-propagating. The amount of the propagation attenuation exhibited the minimum value depending on the thickness of the piezoelectric substrate, but the result of large propagation attenuation was also obtained at the minimum value.

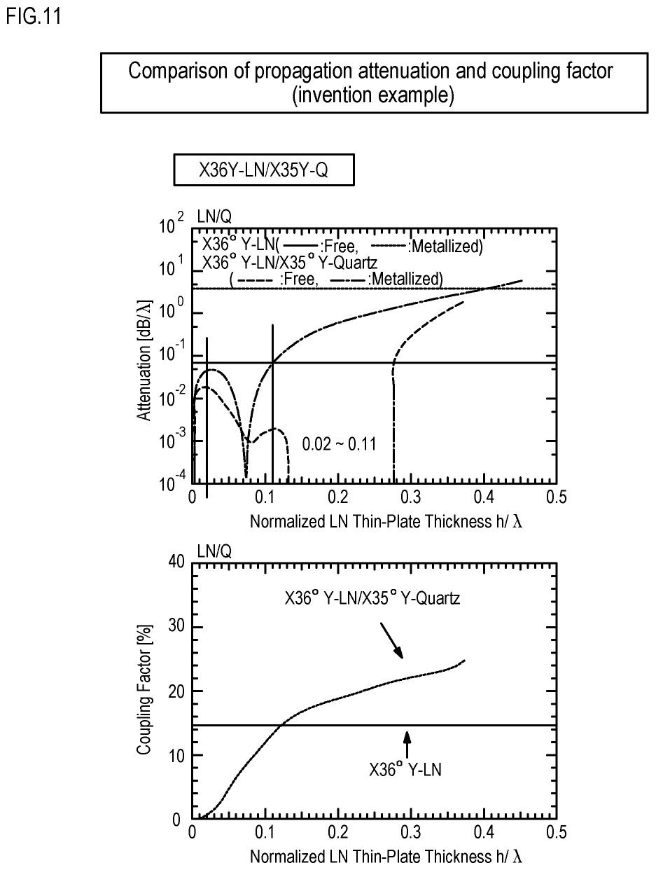

The analysis results of Invention Example assuming the piezoelectric substrate of LN which was X-cut at 36° and Y-propagating and the quartz substrate which was X-cut at 35° and Y-propagating were shown in FIG. 11.

In the present Invention Example, at h/λ of about 0.07, the minimum of the propagation attenuation was 0.0002 dB/λ, so that the result of sufficiently suppressed propagation attenuation was obtained. At h/λ of 0.02 to 0.11, the propagation attenuation is satisfactorily suppressed. By respectively setting the lower and upper limits of the thickness of the piezoelectric substrate to 0.05 and 0.09, the amount of the propagation attenuation can be set to 0.02 dB or less. Similarly, by respectively setting the lower and upper limits to 0.06 and 0.08, the amount of the propagation attenuation can be set to 0.005 dB/λ or less, which is more desirable.

The coupling factor of the present invention was 5%, which was equivalent to that of the related technique.

Next, in the present Invention Example, the influence of the propagation attenuation by the cut angle of the quartz substrate was obtained according to theoretical analysis.

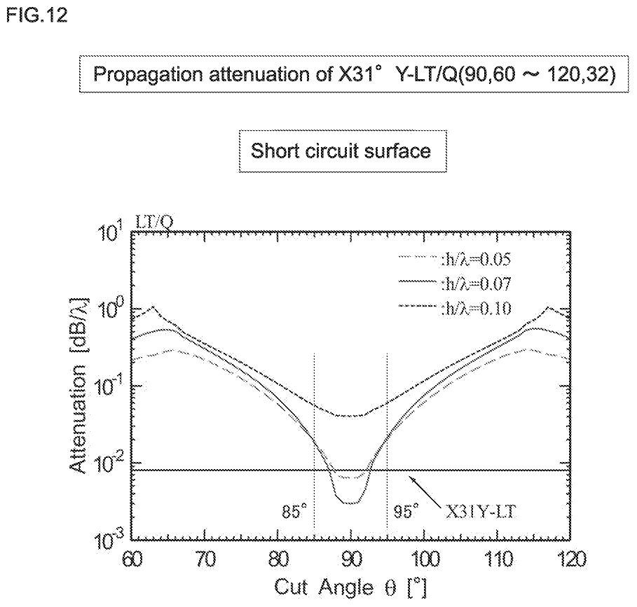

With respect to the bonded substrate in which LT X-cut at 31° and Y-propagating as the piezoelectric substrate and the quartz substrate X-cut at 32° and Y-propagating are bonded to each other, the thickness of the piezoelectric substrate was changed by h/λ (0.05, 0.07, 0.10) according to theoretical analysis, and the cut angle of the quartz substrate was changed within a range of 60 to 120 degrees with respect to the X-axis, to obtain the amount of the propagation attenuation. The results were shown in FIG. 12. A short circuit surface represents the presence of an electrode.

The propagation attenuation represented 0.003 dB/λ as the minimum value in an angle of 90°, i.e., X-cut, regardless of the thickness of the piezoelectric substrate. Even when the cut angle was changed from 90°, the amount of the propagation attenuation was 0.02 or less within a range of 85° to 95°, so that the effect of good suppression of the propagation attenuation was obtained. By respectively setting the lower and upper limits of the cut angle to 88° and 92°, the amount of the propagation attenuation can be set to 0.004 or less, which is more desirable.

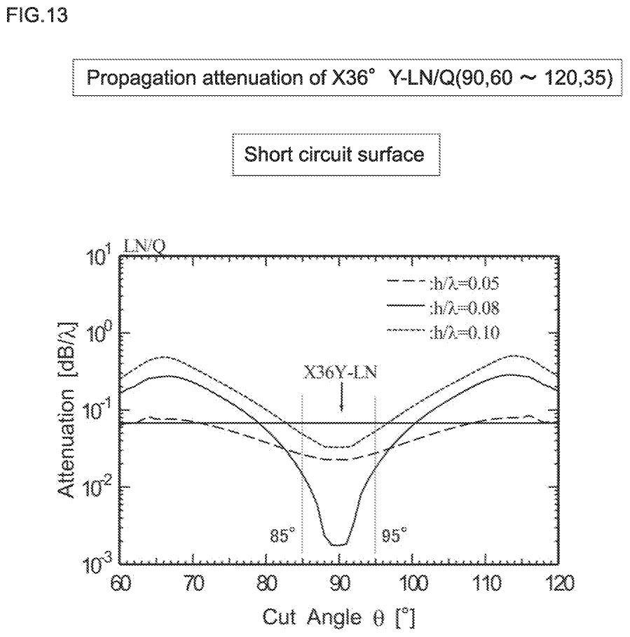

Next, LN X-cut at 36° and Y-propagating was assumed as the piezoelectric substrate, and similarly the influence of the propagation attenuation by the cut angle of the quartz substrate was investigated according to theoretical analysis. The results were shown in FIG. 13.

The propagation attenuation represented 0.002 dB/λ as the minimum value in an angle of 90°, i.e., X-cut, regardless of the thickness of the piezoelectric substrate. Even when the cut angle was changed from 90°, the amount of the propagation attenuation was 0.02 or less within a range of 85° to 95°, so that the effect of good suppression of the propagation attenuation was obtained. By respectively setting the lower and upper limits of the cut angle to 88° and 92°, the amount of the propagation attenuation can be set to 0.003 or less, which is more desirable.

Next, in the present Invention Example, the influence of the propagation attenuation on the propagation direction of quartz was investigated.

LT which was X-cut at 31° and Y-propagating and LN which was X-cut at 36° and Y-propagating were assumed as the piezoelectric substrate, and the propagation direction of the quartz was changed to obtain the amount of the propagation attenuation according to theoretical analysis.

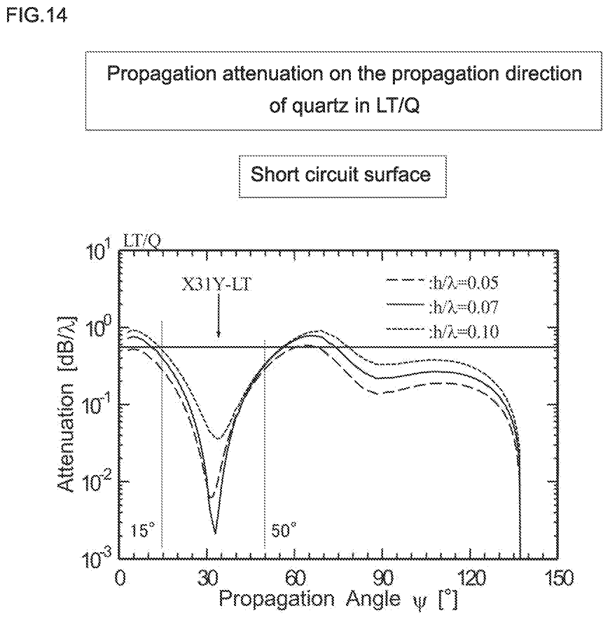

The analysis results when the piezoelectric substrate of LT X-cut at 31° and Y-propagating was used were shown in FIG. 14.

The amount of the propagation attenuation represents the minimum value when the propagation direction of the quartz is set to a 32° Y direction.

With respect to the propagation direction in the quartz substrate, the amount of the propagation attenuation becomes large on both sides with 32° of the propagation direction as the boundary at which the angle of the propagation direction changes. The attenuation can be said to be smaller than that of simplex X31Y-LT at the angle value or less or a range of a small difference between the angles. From this viewpoint, the propagation direction is desirably within a range of 15° to 50°. It is more desirable that the lower and upper limits of the angle are respectively set to 27° and 37°, and the amount of the attenuation becomes less than or equal to that of the simplex X31Y-LT.

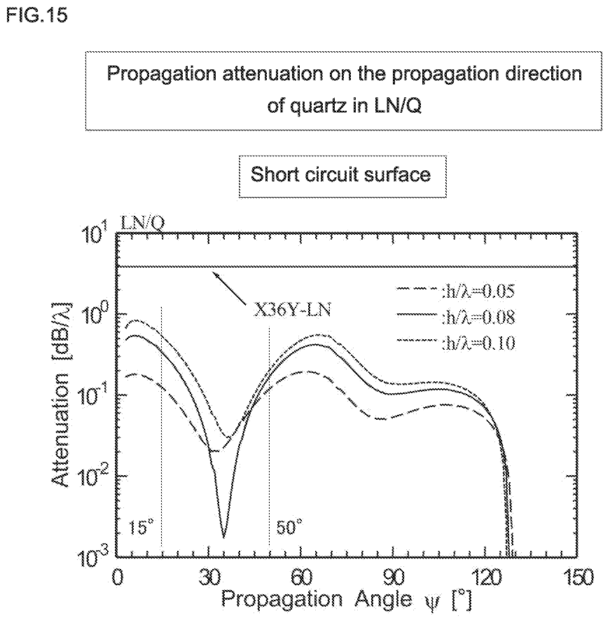

Next, the analysis results when the piezoelectric substrate of LN which was X-cut at 36° and Y-propagating was assumed were shown in FIG. 15.

The amount of the propagation attenuation represents the minimum value when the propagation direction of the quartz is set to a 35° Y direction.

With respect to the propagation direction in the quartz substrate, the amount of the propagation attenuation becomes large on both sides of a range of about 0° and 65° at which the angle changes with 35° as the boundary. The amount of the propagation attenuation is smaller than that of simplex X36Y-LN regardless of the angle of the propagation direction, but by setting the propagation direction to a range of 15° to 50°, the amount of the attenuation is largely reduced. Furthermore, it is more desirable that the lower and upper limits of the angle are respectively set to 30° and 40°.

Next, with respect to Invention Example, LT which was X-cut at 31° and Y-propagating and LN which was X-cut at 36° and Y-propagating were assumed as the piezoelectric substrate, and TCF was obtained by normalizing the thickness h of the piezoelectric substrate by the wavelength λ of the surface acoustic wave according to theoretical analysis. A quartz substrate X-cut at 35° and Y-propagating was used.

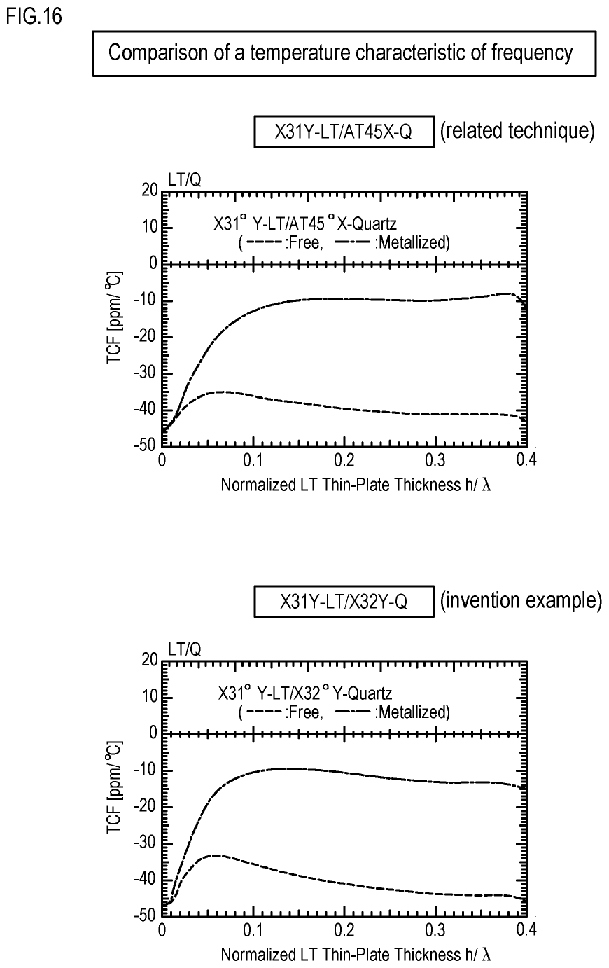

When LT which was X-cut at 31° and Y-propagating was assumed, the relationship between the thickness of the piezoelectric substrate and TCF was shown in FIG. 16.

The present Invention Example has TCF of about −15 ppm/° C. in Metallized, and represents a value equivalent to that of the X-cut 31° Y-LT/AT45° X-quartz substrate of the related technique.

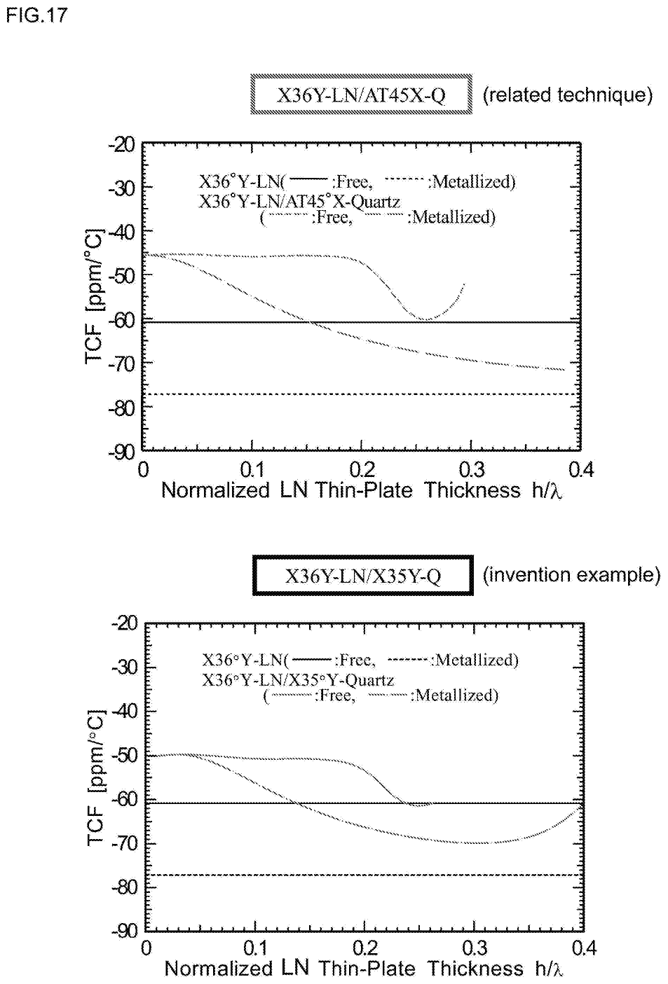

When LN which was X-cut at 36° and Y-propagating was assumed, the relationship between the thickness of the piezoelectric substrate and TCF was shown in FIG. 17.

The present Invention Example has TCF of about −60 to −70 ppm/° C. in Metallized, and represents a value equivalent to that of the X-cut 36°-LN/AT cut 45° X-quartz substrate of the related technique.

Next, the resonance characteristics of the LSAW of an IDT type resonator (λ=8.0 μm, intersection width W=25λ) formed on an LT/quartz bonding structure were analyzed by using the Finite Element Method (FEM). Quartz substrates which were AT-cut at 45° and X-propagating and X-cut at 32° and Y-propagating were assumed, and a piezoelectric substrate having a changed thickness was assumed.

Femtet (manufactured by Murata Software Co., Ltd.) was used as analysis software. As an analysis model, the plate thickness of the supporting substrate was set to 10λ, and a periodic boundary condition (infinite periodic structure) was assumed on both sides of the IDT for one cycle, and a completely matched layer was assumed on the bottom face.

The analysis example of the LSAW of the X-cut 31° Y-LT/AT 45° X-quartz substrate or X-cut 32° Y-quartz substrate structure is shown. An LT plate thickness is 0.15λ, and an electrode Al film thickness is 0.09λ.

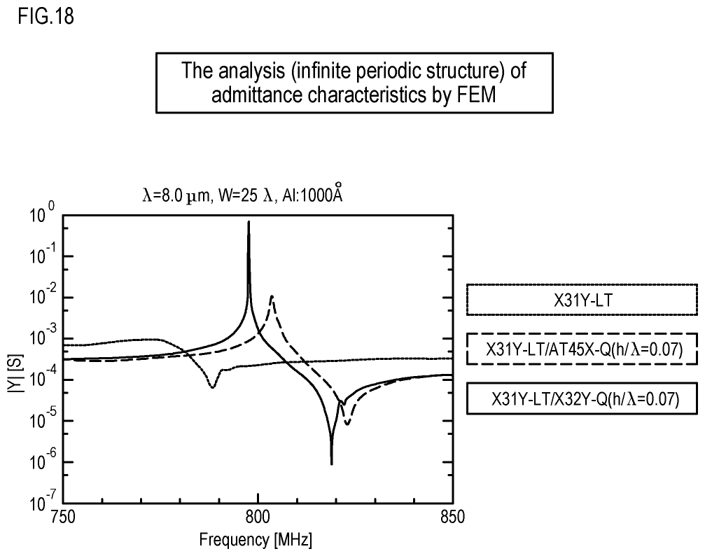

The analysis results are shown in FIG. 18. as compared with when the AT-cut quartz substrate was used, when the X-cut quartz substrate was used, an admittance ratio was increased to 117 dB from 62 dB; a resonance Q value was increased to 53400 from 1000; and a fractional bandwidth was increased to 3.6% from 2.3%.

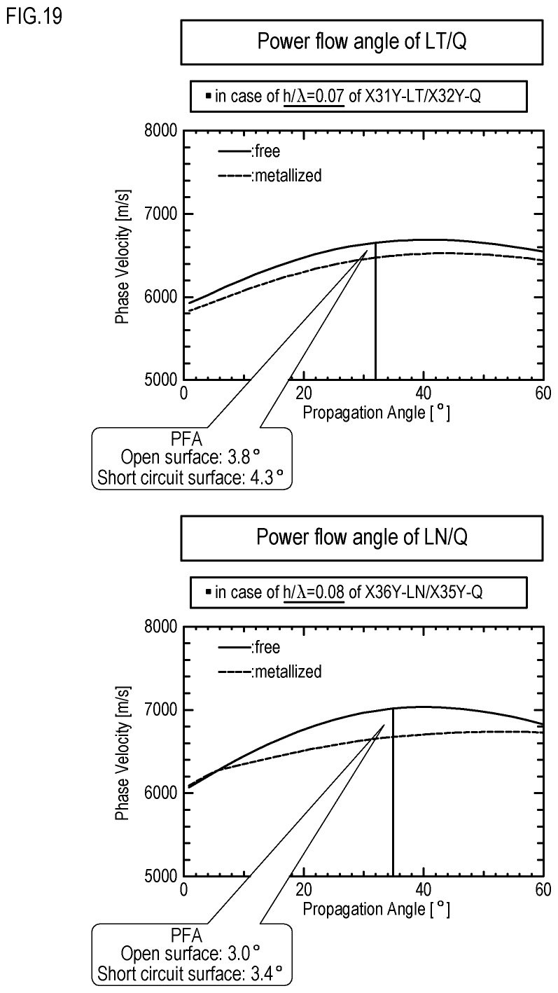

A power flow angle is shown in FIG. 19.

The propagation angle in which the difference between Free and Metallized becomes the largest is shown to be 32° in the X-cut 31° Y-LT/X32° Y-quartz substrate, and 35° in the X-cut 36° Y-LN/X35° X-quartz substrate, coincide with the propagation angle which can reduce the propagation attenuation of the present invention, and have good resonance characteristics.

The analysis (infinite periodic structure) of admittance characteristics by FEM is shown below.
X-cut 31° Y-LT simplex
fractional bandwidth (%): 2.1,
admittance ratio (dB): 23.6,
resonance Q: 43.1,
antiresonance Q: 302.8.
X-cut 31° Y-LT/AT 45X-Q (h/λ=0.1)
fractional bandwidth (%): 0.10,
admittance ratio (dB): 66.1,
resonance Q: 1057,
antiresonance Q: 535.8
X-cut 31° Y-LT/X32Y-Q (h/λ=0.07)
fractional bandwidth (%): 0.07,
admittance ratio (dB): 117,
resonance Q: 53439,
antiresonance Q: 4818

As described above, in the present invention, an X-cut structure quartz substrate was confirmed to be more superior as a supporting substrate to an AT-cut structure quartz substrate conventionally considered to be superior as a supporting substrate.

As above, the present invention has been described based on the aforementioned embodiment and Example. The scope of the present invention is not limited to the contents of the aforementioned description, but proper modifications of the aforementioned embodiment and Example can occur without departing from the scope of the present invention.

### INDUSTRIAL APPLICABILITY

The present invention can be utilized for a SAW resonator, a SAW filter, a highly-functional piezoelectric sensor, and a SAW device and the like.

### REFERENCE SIGNS LIST

1: surface acoustic wave element
1A: surface acoustic wave element
2: quartz substrate
3: piezoelectric substrate
4: bonding interface
5: bonded substrate
6: amorphous layer
10: interdigital electrode
20: processing apparatus
21: vacuum pump
22: discharge apparatus
30: surface acoustic wave element device
31: packaging
32: lid

1. A bonded substrate comprising:
a quartz substrate cut at an intersection angle with a crystal X-axis; and
a piezoelectric substrate laminated on the quartz substrate.

2. The bonded substrate according to claim 1, wherein a cut angle of the quartz substrate has an angle in the range of 85 to 95 degrees with respect to the crystal X-axis.

3. The bonded substrate according to claim 1, wherein:
the quartz substrate has a surface acoustic wave propagation direction set on a crystal Y direction side; and
the piezoelectric substrate has a surface acoustic wave propagation direction set in the propagation direction.

4. The bonded substrate according to claim 1, wherein the surface acoustic wave propagation direction of the quartz substrate has an angle of 15 to 50 degrees with respect to a crystal Y-axis.

5. The bonded substrate according to claim 1, wherein the piezoelectric substrate is lithium niobate or lithium tantalate.

6. The bonded substrate according to claim 1, wherein the piezoelectric substrate is lithium tantalate X-cut at 31° and Y propagating or lithium niobate X-cut at 36° and Y propagating.

7. The bonded substrate according to claim 5, wherein the piezoelectric substrate has a thickness h having a relationship of 0.02 to 0.11λ with respect to a wavelength λ of a surface acoustic wave.

8. The bonded substrate according to claim 1, wherein the piezoelectric substrate is for exciting a longitudinal-type leaky surface acoustic wave.

9. The bonded substrate according to claim 1, wherein an amount of surface acoustic wave propagation attenuation is 0.1 dB/λ or less with respect to a wavelength λ of a surface acoustic wave.

10. A surface acoustic wave element comprising at least one interdigital electrode on a principal surface of the piezoelectric substrate in the bonded substrate according to claim 1.

11. A surface acoustic wave element device, wherein the surface acoustic wave element according to claim 10 is sealed in a package.

12. A method for manufacturing a bonded substrate comprising a quartz substrate and a piezoelectric substrate bonded to each other, the method comprising:
cutting quartz at an intersection angle with a crystal X-axis of the quartz to provide a quartz substrate;
setting a surface acoustic wave propagation direction on a Y-axis direction side in the quartz substrate;
providing a piezoelectric substrate having a surface acoustic wave propagation direction set according to the propagation direction;
laminating the piezoelectric substrate on the quartz substrate; and
bonding the quartz substrate and the piezoelectric substrate to each other directly or with an intermediate layer interposed therebetween.

13. The method for manufacturing a bonded substrate according to claim 12 comprising:
irradiating a bonding surface of the quartz substrate and a bonding surface of the piezoelectric substrate with ultraviolet light under a reduced pressure;
contacting the bonding surface of the quartz substrate and the bonding surface of the piezoelectric substrate with each other after the irradiation; and
pressurizing the quartz substrate and the piezoelectric substrate in a thickness direction to bond the bonding surfaces with each other.

14. The method for manufacturing a bonded substrate according to claim 13, wherein heating at a predetermined temperature is performed during the pressurization.

15. The method for manufacturing a bonded substrate according to claim 12, wherein the intermediate layer is an amorphous layer.
